(19) United States
(12) Patent Application Publication
(10) Pub. No.: US 2014/0146479 A1
(43) Pub. Date: May 29, 2014

(54) FLEXIBLE THERMAL TRANSFER STRIPS

(71) Applicants: Kevin Donald Kilroy, Rockford, IL (US); Darren L. Miller, Loves Park, IL (US); Jeffrey T. Wavering, Rockford, IL (US)

(72) Inventors: Kevin Donald Kilroy, Rockford, IL (US); Darren L. Miller, Loves Park, IL (US); Jeffrey T. Wavering, Rockford, IL (US)

(73) Assignee: Hamilton Sundstrand Corporation, Windsor Locks, CT (US)

(21) Appl. No.: 13/687,007

(22) Filed: Nov. 28, 2012

(51) Int. Cl. H05K 7/20

(52) U.S. Cl. CPC H05K 7/2039
USPC 361/717

(57) ABSTRACT

A system for use between a heat generating electronic device having a die having a shape placed thereon and a heat sink, includes a thermally conductive slug having a plurality of edges; a plurality of discrete strips each of the strips having a proximal end attaching to one of the edges of the thermally conductive slug, a distal end wherein the distal end is rigid for attachment to the heat sink, a flexible portion between the distal end and the thermally conductive slug wherein the slug may move as the electronic device moves and wherein the strips are comprised of two of more discrete layers, or strands that create a braid.

### TECHNICAL BACKGROUND

This invention relates generally to the dissipation of thermal energy generated by semiconductor devices, such as memory chips.

### BACKGROUND

Some systems that include single chip or multi-chip integrated circuit assemblies where the devices are mounted on a substrate with solder bonds, and a cap mounted in close proximity to the backsides of the devices require cooling.

The high circuit densities in modern integrated circuit semiconductor devices require that the heat generated by their operation be efficiently removed in order to maintain the temperature of the devices within limits that will keep the operating parameters of the devices within predetermined ranges, and also prevent destruction of the device by overheating.

The problems of heat removal are increased when the device is connected to the supporting substrate with solder terminals that electrically connect the device to appropriate terminals on the substrate. In such solder-bonded devices, the heat transfer that can be accomplished through the solder bonds is limited, as compared to back-bonded devices. Cooling of semiconductor devices can be achieved by immersing the devices in a suitable liquid coolant. However, these cooling techniques can result in corrosion of the device and substrate metallurgy, and also present rework problems. Cooling can also be achieved by using a fan to create forced air convection. However, system level requirements sometimes prohibit fan usage due to reliability. Cooling can also be achieved by providing a conducting link of material between the device and the cap or cold plate.

### SUMMARY

According to a non-limiting embodiment described herein, a system for use between a heat generating electronic device having a die having a shape placed thereon and a heat sink, includes a thermally conductive slug having a plurality of edges; a plurality of discrete strips each of the strips having a proximal end attaching to one of the edges of the thermally conductive slug, a distal end wherein the distal end is rigid for attachment to the heat sink, a flexible portion between the distal end and the thermally conductive slug wherein the slug may move as the electronic device moves and wherein the strips are comprised of two of more discrete layers, or strands that create a braid.

As disclosed in any previous claim the strips include strands only.

As disclosed in any previous claim, the strands include two or more strands made of copper, silver, aluminum, or graphite.

As disclosed in any previous claim, the strips include layers only.

As disclosed in any previous claim, the layers include two or more layers made of copper, silver, aluminum, or graphite.

As disclosed in any previous claim, the system further comprises a spring biasing the slug for urging the slug against the die.

As disclosed in any previous claim, the system further comprises a frame for disposal between the discrete strips and the slug, the frame having a plurality of sides corresponding to the same number of strips, each of the distal ends of the strips attaching to a side of the frame.

As disclosed in any previous claim, the frame, the strips, and the slug comprise a preform.

As disclosed in any previous claim, the system further comprises a spring abutting the slug.

According to a further non-limiting embodiment described herein, a system for dissipating heat, the system includes a heat generating electronic device; a heat sink; and an assembly disposed between the heat sink and the electronic device, the assembly including: a thermally conductive slug abutting the heat generating electronic device and having a plurality of edges; a plurality of discrete strips each of the strips having a proximal end attaching to one of the edges of the thermally conductive slug, a distal end wherein the distal end is rigid for attachment to the heat sink, and a flexible portion between the distal end and the thermally conductive slug wherein the slug may move as the electronic device moves and wherein the strips are comprised of two of more discrete layers, or strands that create a braid.

As disclosed in any previous claim, the strips include strands only.

As disclosed in any previous claim, the strands include two or more strands made of copper, silver, aluminum, or graphite.

As disclosed in any previous claim, the strips include layers only wherein the layers include two or more layers made of copper, silver, aluminum, or graphite.

As disclosed in any previous claim, the system further comprises a spring biasing the slug for urging the slug against the die.

As disclosed in any previous claim, the system further comprises a die disposed atop the heat generating electronic device between the heat generating electronic device and the slug.

As disclosed in any previous claim, the system further comprises a thermal layer disposed between the heat generating electronic device and the slug.

As disclosed in any previous claim, the system further comprises a frame for disposal between for disposal between the discrete strips and the slug, the frame having a plurality of sides corresponding to the same number of strips, each of the distal ends of the strips attaching to a side of the frame.

As disclosed in any previous claim, the frame, the strips, and the slug comprise a preform.

As disclosed in any previous claim, the system further comprises a spring abutting the slug.

As disclosed in any previous claim, the preform is preattached to either of the heat generating electronic device or the heat sink

These and other features may be best understood from the following drawings and specification.

### BRIEF DESCRIPTION OF THE DRAWINGS

FIG. 1 shows a side view of an electronic heat sink system.

FIG. 2 shows a side view of a further embodiment of the electronic heat sink system of FIG. 1 incorporating a spring therein.

FIG. 3 shows an embodiment of an attachment system used in the electronic heat sink system of FIGS. 1 and 2.

FIG. 4 shows a top view of the attachment system of FIG. 3 through a heat sink used in the electronic heat sink system of FIGS. 1 and 2.

FIG. 5 shows a top view of an alternative embodiment of the attachment system of FIG. 3.

### DETAILED DESCRIPTION

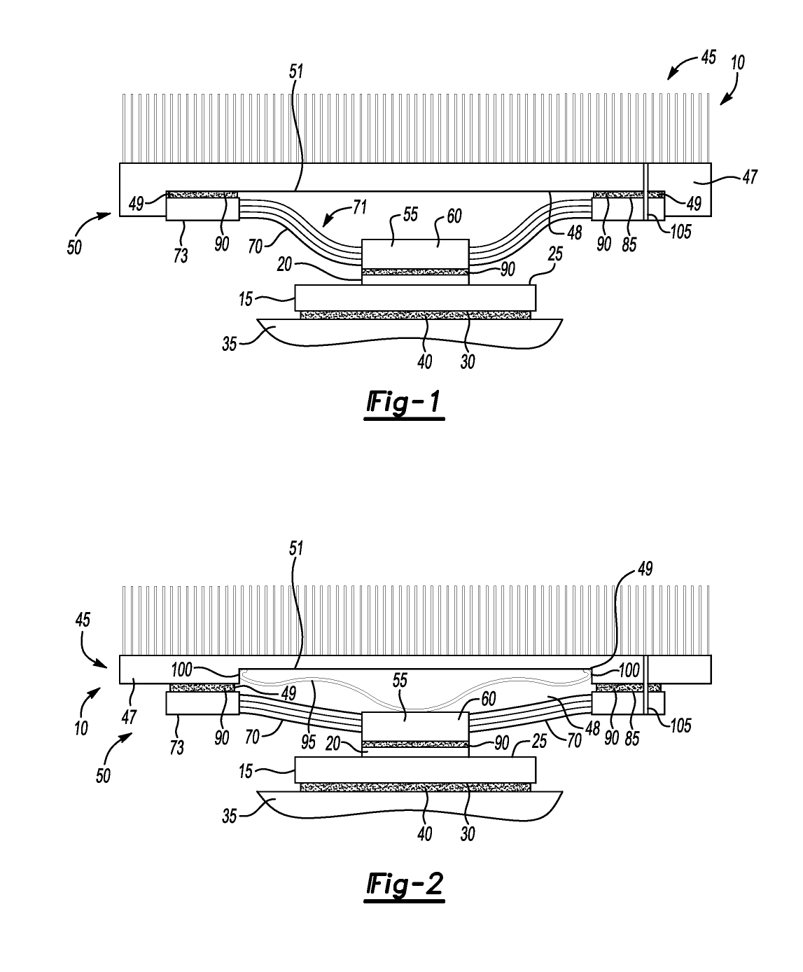

Referring to FIG. 1, an electronic heat sink system 10 is shown. A heat generating electronic device such as a microprocessor 15, which has a die 20, which may be non-compressive and thermally conductive, placed on a first surface 25 (i.e., shown as a top surface herein) thereof, also has a second surface 30 (i.e., shown as bottom surface) opposite the first surface 25. The microprocessor 15 may have a plurality of connectors (not shown) attaching thereto as is known in the art. The microprocessor 15 is typically attached to a cold plate 35 by soldering 40 or the like. A heat sink 45 is placed in register with the microprocessor 15. The heat sink has a flat body 47 having a recess 48 therein. The recess 48 has a plurality of radial edges 49 that lead to an inner surface 51 therein. Unless a spring is used, as will be discussed infra, a recess 48 may not be desired.

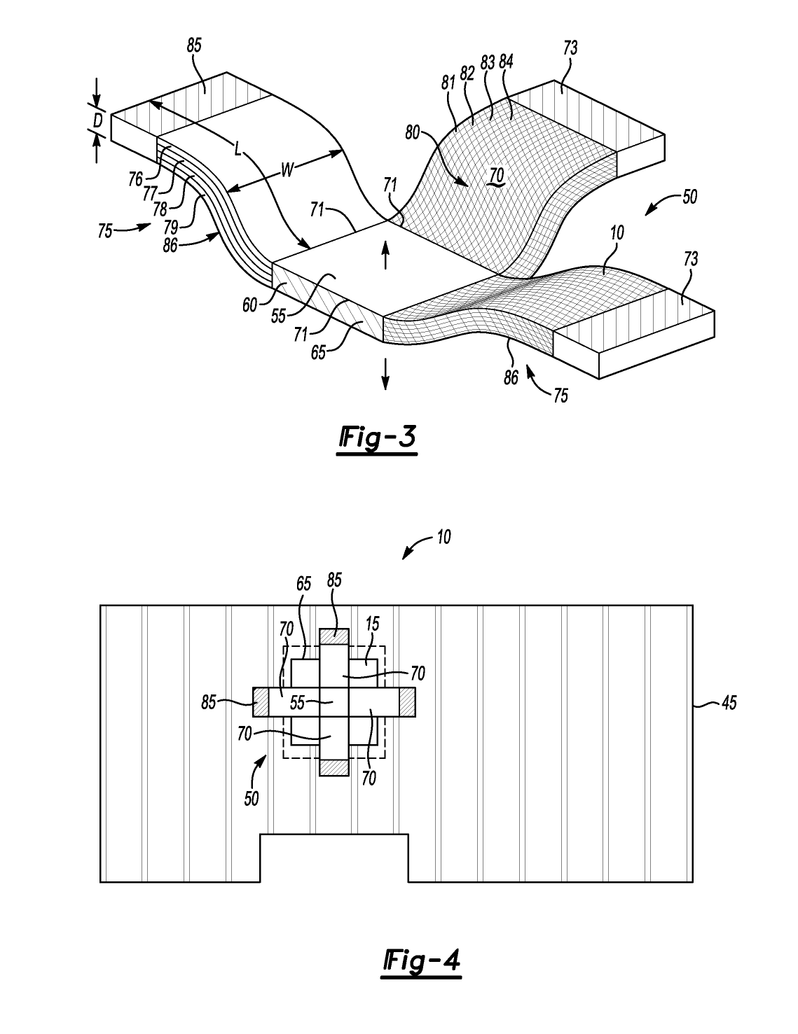

Referring now to FIGS. 1, 2, and 3, an attachment system 50 for attaching the microprocessor to the heat sink 45 is shown. The attachment system 50 has a thermally conductive slug 55 that has a body 60 that may be made of copper or the like and that is generally rectangular and rigid. The slug 55 can be any shape but generally conforms to the shape of the die 20 of the microprocessor to ensure the efficiency of heat transfer away from the microprocessor 15. As such, if the die 20 is rectangular or other shaped, the body 60 is also rectangular or other shaped. The body 60, in this instance shown, has four side edges 65. Strips 70 are thermally conductive, generally flexible or bendable and have a width W and a length L. Each strip 70 has a proximal edge portion 71 attaching to an edge 65 of the body 60. Each strip has a distal edge portion 73, which may be rigid having a portion 85 facing towards the heat sink 45, and has a depth D. The strip may have a plurality of layers 75, which may be comprised of copper layers 76, silver layers 77, aluminum layers 78, or graphite layers 79. Each strip 70 may also be comprised of braids 80. For instance, the strands of the braids 80 may be a copper strand 81, an aluminum strand 82, a silver strand 83, or a graphite strand 84. Each strip 70 is non-linear length-wise (e.g., has bends 86) so the strip 70 length L may change as will be discussed infra. Thermal layer 90, which may be an adhesive or grease thermally connects the slug 55 to the die 20.

Each strip 70 may have a particular composition so that each strip acts as a spring to urge the slug 55 against the compressive die 20 to ensure contact between the slug 55 and the die 20. If the electronic heat sink system 10 is to be used in an environment where grease that may be used would not be expected to withstand the vibration experienced in the electronic heat sink system 10, a spring 95, such as a leaf or other spring, may be utilized to ensure that the slug 55 is maintained (i.e., abutting or attaching) against the die 20 in all instances to ensure that thermal transfer is carried out in every instance. It is also possible that the flexible strips 70 do not act as springs, but are flexible/bendable to enable installation where manufacturing and installation tolerances, which may not always be ideal, have to be accounted for during assembly.

To install the attachment system between the microprocessor 15 and the heat sink 45, the slug 55 abuts the die 20 with either a thermal layer 90 of adhesive or grease therebetween. The strips 70 are bent or flexed inwardly or outwardly relative to the slug 55 to the desired length L so that the distal edge portions 73 abut the flat body 47 at a desired location on the heat sink 45. The portions 85 may be attached to the flat body 47 by using a thermal layer 90 such as adhesive therebetween, by mechanical attachment 105 by rivets or nuts and bolts, or both to ensure continued contact with the heat sink 45. The distal edge portion 73 may also be connected to the radial edge 49 and to the inner surface 51 to maximize heat transfer to the heat sink 45.

In another embodiment referring to FIG. 2, the portions 85 may be attached to the flat body 47 outside of the recess 48 and the spring 95 is disposed in the recess 48 between the slug 55 and the flat body 47. The spring 95 is in contact with the slug 55 to urge the slug 55 against the die 20. Ends 100 of the spring 95 abut the inner surface 51 and radial edges 49.

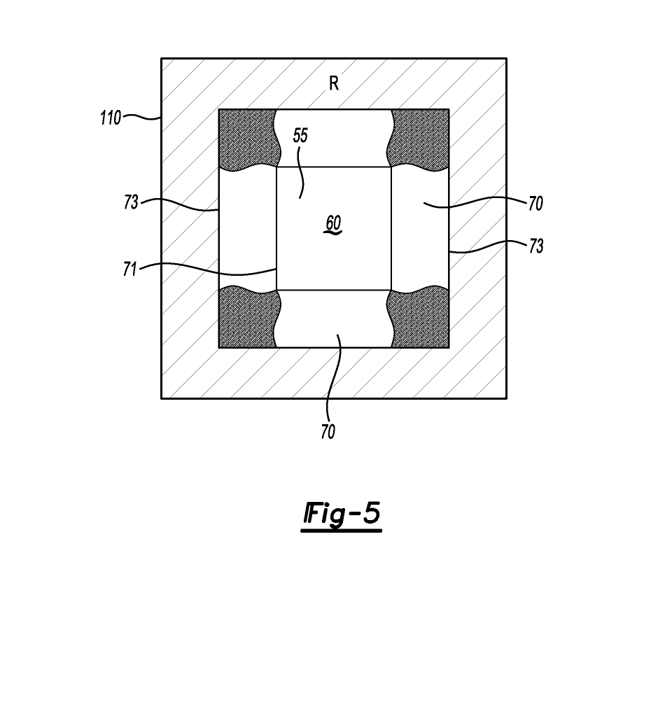

In another embodiment referring to FIG. 5, the distal edge portions 73 may be attached to a thermally conductive frame 110. The frame has the same number of sides as there are strips 70. The frame 110 attaches to the flat body 47 either inside or outside of the recess 48. As above, the spring 95 is disposed in the recess 48 between the slug 55 and the flat body 47. The spring 95 is in contact with the slug 55 to urge the slug 55 against the die 20. Ends 100 of the spring 95 abut the inner surface 51 and radial edges 49. The frame 110, the strips 70 and the slug 55 may be preassembled as a preform to ease the assembly operation. The installation of this embodiment is as above. The frame 110 is disposed between the microprocessor 15 and the heat sink 45. The slug 55 abuts the die 20 with either a thermal layer 90 of adhesive or grease therebetween. The strips 70 are bent or flexed inwardly or outwardly relative to the slug 55 to the desired length L so that the frame 110 abuts the flat body 47 at a desired location on the heat sink 45. The spring 95 may also be disposed between the slug 55 and the heat sink 45. The spring 95 may also be part of the preform by attaching the spring to the slug 55. The preform may be pre-attached to the die 20 or the heat sink 45.

Although an embodiment of this invention has been disclosed, a worker of ordinary skill in this art would recognize that certain modifications would come within the scope of this invention. For that reason, the following claims should be studied to determine the true scope and content of this invention.

1. A system for use between a heat generating electronic device having a die having a shape placed thereon and a heat sink, said system comprising;
a thermally conductive slug having a plurality of edges;
a plurality of discrete strips each of said strips having
a proximal end attaching to one of said edges of said thermally conductive slug,
a distal end wherein said distal end is rigid for attachment to said heat sink,
a flexible portion between said distal end and said thermally conductive slug
wherein said slug may move as said electronic device moves and wherein said strips are comprised of two of more discrete layers, or strands that create a braid.

2. The system of claim 1 wherein said strips include strands only.

3. The system of claim 1 wherein said strands include two or more strands made of copper, silver, aluminum, or graphite.

4. The system of claim 1 wherein said strips include layers only.

5. The system of claim 1 wherein said layers include two or more layers made of copper, silver, aluminum, or graphite.

6. The system of claim 1 further comprising a spring biasing said slug for urging said slug against said die.

7. The system of claim 1 further comprising a frame for disposal between said discrete strips and said slug, said frame having a plurality of sides corresponding to the same number of strips, each of said distal ends of said strips attaching to a side of the frame.

8. The system of claim 7 wherein said frame, said strips, and said slug comprise a preform.

9. The system of claim 7 further comprising a spring abutting said slug.

10. A system for dissipating heat, said system comprising;
a heat generating electronic device;
a heat sink; and
an assembly disposed between said heat sink and said electronic device, said assembly including:
a thermally conductive slug abutting said heat generating electronic device and having a plurality of edges;
a plurality of discrete strips each of said strips having
a proximal end attaching to one of said edges of said thermally conductive slug,
a distal end wherein said distal end is rigid for attachment to said heat sink, and
a flexible portion between said distal end and said thermally conductive slug wherein said slug may move as said electronic device moves and wherein said strips are comprised of two of more discrete layers, or strands that create a braid.

11. The system of claim 10 wherein said strips include strands only.

12. The system of claim 10 wherein said strands include two or more strands made of copper, silver, aluminum, or graphite.

13. The system of claim 10 wherein said strips include layers only wherein said layers include two or more layers made of copper, silver, aluminum, or graphite.

14. The system of claim 10 further comprising a spring biasing said slug for urging said slug against said die.

15. The system of claim 10 further comprising a die disposed atop said heat generating electronic device between said heat generating electronic device and said slug.

16. The system of claim 15 further comprising a thermal layer disposed between said heat generating electronic device and said slug.

17. The system of claim 10 further comprising a frame for disposal between for disposal between said discrete strips and said slug, said frame having a plurality of sides corresponding to the same number of strips, each of said distal ends of said strips attaching to a side of the frame.

18. The system of claim 17 wherein said frame, said strips, and said slug comprise a preform.

19. The system of claim 17 further comprising a spring abutting said slug.

20. The system of claim 17 wherein said preform is preattached to either of said heat generating electronic device or said heat sink
